(19) United States
(12) Patent Application Publication
(10) Pub. No.: US 2026/0164721 A1
(43) Pub. Date: Jun. 11, 2026

(54) Display Substrate and Preparation Method Therefor, and Display Apparatus

(71) Applicants: Chongqing BOE Optoelectronics Technology Co., Ltd., Chongqing (CN); BOE Technology Group Co., Ltd., Beijing (CN); Beijing BOE Technology Development Co., Ltd., Beijing (CN)

(72) Inventors: Wei SHEN, Beijing (CN); Hui GUO, Beijing (CN); Zhonghao HUANG, Beijing (CN); Xu WU, Beijing (CN); Chengjun QI, Beijing (CN); Zhiyong NING, Beijing (CN); Rui WANG, Beijing (CN); Kunkun GAO, Beijing (CN); Haolan FANG, Beijing (CN)

(21) Appl. No.: 18/710,174

(22) PCT Filed: Apr. 19, 2023
(86) PCT No.: PCT/CN2023/089340

§ 371 Date: May 14, 2024

(51) Int. Cl. H10D 30/67; H10D 30/01; H10D 86/60

(52) U.S. Cl. CPC H10D 30/6757; H10D 30/0316; H10D 30/6732; H10D 86/60

(57) ABSTRACT

The present disclosure provides a display substrate, a preparation method therefor, and a display apparatus. The display substrate includes: a semiconductor layer (41), including contact regions and a channel region (411) located between the contact regions; a contact electrode (30), at least a portion of which is disposed on a side of the contact region away from the base substrate (101) and electrically connected to the contact region; an auxiliary layer (42), the auxiliary layer (42) including a host material and a second element, the first element and the second element having the same atomic number, and the host material being the same as the material of the contact region.

### CROSS-REFERENCE TO RELATED APPLICATION

The present application is a U.S. National Phase Entry of International Application No. PCT/CN2023/089340 having an international filing date of Apr. 19, 2023, the entire content of which is hereby incorporated by reference.

### TECHNICAL FIELD

The present disclosure relates to, but is not limited to, the field of display technologies, and in particular to a display substrate and a method for preparing a display substrate, and a display apparatus.

### BACKGROUND

An oxide Thin Film Transistor (TFT for short) has currently become a mainstream Thin Film Transistor fabrication technology for its characteristics of good uniformity, high mobility, etc. A material of an active layer of the existing oxide Thin Film Transistor usually includes indium gallium zinc oxide IGZO, and the back channel etching structure (BCE) has advantages of simple process flow and controllable TFT size, etc.

### SUMMARY

The following is a summary of subject matters described herein in detail. This summary is not intended to limit the protection scope of the claims.

In one aspect, the present disclosure provides a display substrate including a base substrate and a transistor disposed on the base substrate;

The transistor includes:
a semiconductor layer, including contact regions and a channel region located between the contact regions;
a contact electrode, at least a portion of which is disposed on a side of a contact region away from the base substrate and electrically connected to the contact region, and the material of which includes a first element; and
an auxiliary layer, disposed between the contact electrode and the semiconductor layer, a surface of a side of the auxiliary layer away from the base substrate being in contact with the contact electrode, a surface of a side of the auxiliary layer close to the base substrate being in contact with the contact regions, the auxiliary layer including a host material and a second element, the first element and the second element having a same atomic number, and the host material being the same as a material of the contact region.

In an exemplary implementation, the auxiliary layer is disposed between the contact electrode and the contact region of the semiconductor layer, at least a portion of the channel region is not overlapped with an orthographic projection of the auxiliary layer on the base substrate, and the auxiliary layer and the contact region are of an integrated structure.

In an exemplary implementation, a vertical distance between the surface of a side of the auxiliary layer away from the base substrate and a surface of the base substrate is L3, and a vertical distance between a surface of a side of the channel region away from the base substrate and the surface of the base substrate is L2, and L3≥L2>2 nm.

In an exemplary implementation, 2 nm≤|L3−L2|≤20 nm.

In an exemplary implementation, the contact region includes a side surface close to a side of the channel region, and a slope angle of the side surface is 50° to 60°.

In an exemplary implementation, a content of the second element in the auxiliary layer is 0.1% to 10%.

In an exemplary implementation, the contact regions include the first element and the semiconductor material, and a content of the first element in the contact regions is not more than 0.10%.

In an exemplary implementation, a ratio of a thickness of the auxiliary layer to a thickness of the contact region is 1:10 to 1:3.

In an exemplary implementation, a ratio of a thickness of the contact region to a thickness of the channel region is 1:1 to 5:1.

In an exemplary implementation, the first element and the second element include at least one of aluminum, copper, molybdenum, nickel, titanium, and niobium.

In an exemplary implementation, the material of the semiconductor layer is one or more of a metal oxide, an amorphous silicon, and a polysilicon.

In an exemplary implementation, the second element is molybdenum, and a difference between a distance of the surface of the side of the auxiliary layer away from the base substrate to a surface of the base substrate, and a distance of a surface of a side of the channel region away from the base substrate to a surface of the base substrate, is greater than or equal to 9 nm and less than or equal to 20 nm.

In an exemplary implementation, a gate is further included, which is located on a side of the semiconductor layer close to the base substrate and is insulated from the semiconductor layer. The gate is overlapped with an orthographic projection of the channel region of the semiconductor layer on the base substrate.

In an exemplary implementation, the contact electrode includes a first material layer, a second material layer, and a third material layer disposed between the first material layer and the second material layer.

In an exemplary implementation, the transistor includes:
the semiconductor layer, including a first contact region, a second contact region and a channel region between the first contact region and the second contact region;
a first contact electrode and a second contact electrode, at least a portion of the first contact electrode being disposed on a side of the first contact region away from the base substrate and electrically connected to the first contact region, and at least a portion of the second contact electrode being disposed on a side of the second contact region away from the base substrate and electrically connected to the second contact region;
a first auxiliary layer, disposed between the first contact electrode and the first contact region, a surface of a side of the first auxiliary layer away from the base substrate being in contact with the first contact electrode, a material of the first contact electrode including a first element, the first auxiliary layer including a first host material and a second element, the first element and the second element having a same atomic number, and the first host material being the same as a material of the first contact region; and
a second auxiliary layer, disposed between the second contact electrode and the second contact region, a surface of a side of the second auxiliary layer away from the base substrate being in contact with the second contact electrode, a material of the second contact electrode including a first element, the second auxiliary layer including a second host material and a second element, the first element and the second element having the same atomic number, and the second host material being the same as the material of the second contact region.

In another aspect, the present disclosure further provides a display apparatus, including the display substrate described above.

In yet another aspect, the present disclosure further provides a method for preparing a display substrate, including:
forming a semiconductor layer on a base substrate, the semiconductor layer including contact regions and a channel region located between the contact regions;
forming a metal film covering the semiconductor layer on the base substrate, a material of the metal film including a first element, the first element of at least a portion of the metal film intruding into the semiconductor layer to form an auxiliary film;
forming a contact electrode with the metal film through a patterning process, and exposing the auxiliary film on the channel region;
removing the exposed auxiliary film on at least a portion of the channel region, exposing a surface of at least the portion of the channel region, retaining the auxiliary film on the contact region to form an auxiliary layer with the auxiliary film, the auxiliary layer including a host material and a second element, the first element and the second element having a same atomic number, and the host material being the same as a material of the contact region.

In an exemplary implementation, the same patterning process is used to form the contact electrode with the metal film and to remove the exposed auxiliary film on at least the portion of the channel region.

In an exemplary implementation, removing the exposed auxiliary film on at least the portion of the channel region includes:
etching the metal film with an etching liquid to form the contact electrode with the metal film and to expose the auxiliary film on the channel region;
etching the exposed auxiliary film on at least the portion of the channel region with the etching liquid to remove the exposed auxiliary film on the channel region.

In an exemplary implementation, a ratio of an etching rate of the metal film in the etching liquid to an etching rate of the auxiliary film in the etching liquid is 50:1 to 5:1.

Other aspects may become clear after the drawings and the detailed description are read and understood.

### BRIEF DESCRIPTION OF DRAWINGS

The drawings are used for providing an understanding of technical solutions of the present application and form a part of the specification. They are used for explaining the technical solutions of the present application together with embodiments of the present application, but do not constitute a limitation on the technical solutions of the present application.

FIG. 1a is a cross-sectional view of a transistor in a display substrate in the related art.

FIG. 1b is a graph of an X-ray Photoelectron Spectrometer (XPS) of a transistor in a display substrate in the related art.

FIG. 2 is a schematic structural diagram of a display substrate according to an embodiment of the present application.

FIG. 3 is a cross-sectional view of a display substrate according to an embodiment of the present disclosure.

FIG. 4 is a first cross-sectional view of a transistor in a display substrate according to an embodiment of the present disclosure.

FIG. 5 is a second cross-sectional view of a transistor in a display substrate according to an embodiment of the present disclosure.

FIG. 6a is a schematic diagram for illustrating the method for preparing a display substrate after a gate is formed according to an embodiment of the present disclosure.

FIG. 6b is a schematic diagram for illustrating the method for preparing a display substrate after a semiconductor layer is formed according to an embodiment of the present disclosure.

FIG. 6c is a schematic diagram for illustrating the method for preparing a display substrate after a metal film is formed according to an embodiment of the present disclosure.

FIG. 7 is a graph of an X-ray Photoelectron Spectrometer (XPS) of a channel region of a semiconductor layer in a base substrate according to an embodiment of the present disclosure.

FIG. 8 is a graph of an X-ray Photoelectron Spectrometer (XPS) of a contact region of a semiconductor layer in a base substrate according to an embodiment of the present disclosure.

### DETAILED DESCRIPTION

To make objectives, technical solutions, and advantages of the present disclosure clearer, the embodiments of the present disclosure will be described in detail below in with reference to the accompany drawings. It is to be noted that the implementation modes may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the drawings schematically illustrate ideal examples, and a mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction by which each constituent element is described. Therefore, appropriate replacements based on situations are allowed, and the positional relationships are not limited to the expressions described in the specification.

In the specification, unless otherwise specified and defined, terms “mounting”, “mutual connection”, and “connection” should be understood in a broad sensing. For example, a connection may be a fixed connection, a detachable connection, or an integral connection; it may be a mechanical connection or a connection; it may be a direct connection, an indirect connection through a middleware, or internal communication inside two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In cases that transistors with opposite polarities are used, or a current direction changes during operation of a circuit, or the like, functions of the “source electrode” and the “drain electrode” are sometimes interchangeable. Therefore, the “source electrode” and the “drain electrode” are interchangeable in the specification.

In the specification, a “connection” includes a case where composition elements are connected together through an element with a certain electrical action. An “element with a certain electrical action” is not particularly limited as long as electric signals between the connected composition elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulating film” may be replaced with an “insulating layer” sometimes.

In the present disclosure, “about” refers to that a boundary is not defined so strictly and numerical values within a range of process and measurement errors are allowed.

According to the research of the inventors of the present application, it is found that during the fabrication process of the back channel, it is necessary to directly deposit a source-drain metal electrode on the surface of the active layer, and the metal electrode is usually made of metal materials such as aluminum (Al) and copper (Cu). For example, as the metal electrode is made of copper and the active layer is made of indium gallium zinc oxide (IGZO), the copper element will diffuse into the active layer during the formation of the metal electrode, which will affect the characteristics of thin film transistor (TFT). In addition, the contact adhesion between the copper metal and the gate insulating layer is poor, which makes the metal electrode easy to fall off.

In order to solve the problem of metal electrode falling off, the metal electrode may adopt a multi-layer metal structure, such as a multi-layer stacked structure of molybdenum (Mo)/aluminum (Al)/molybdenum (Mo), molybdenum-niobium alloy (MoNb)/copper (Cu)/molybdenum-niobium alloy (MoNb), molybdenum-niobium-titanium alloy (MTD)/copper (Cu)/molybdenum-niobium-titanium alloy (MTD), etc.

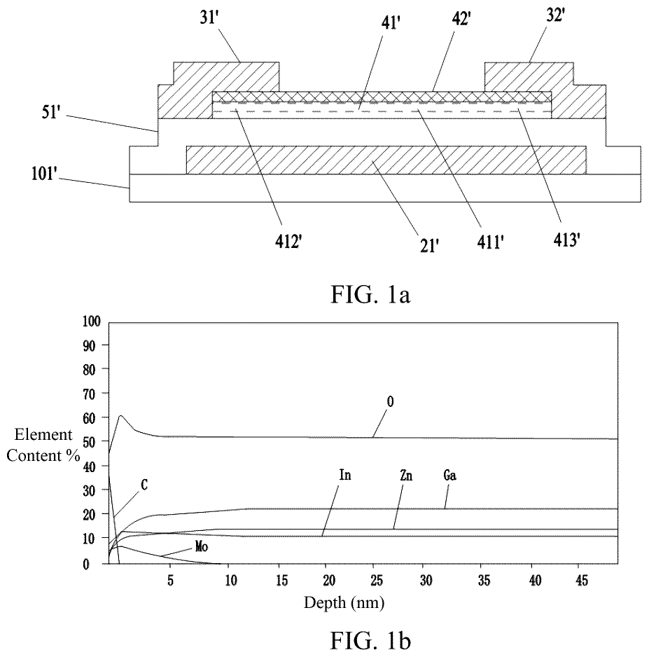

FIG. 1a is a cross-sectional view of a transistor in a display substrate in a related art. As shown in FIG. 1a, a transistor in a display substrate of the related art includes: a base substrate 101′, and a gate 21′, a gate insulating layer 51′, a semiconductor layer 41′, a first electrode 31′, and a second electrode 32′ disposed sequentially along a direction away from the base substrate 101′. The semiconductor layer 41′ includes a channel region 411′ and a first contact region 412′ and a second contact region 413′ located on the opposite two sides of the channel region 411′. A portion of the first electrode 31′ is disposed on the surface of the first contact region 412′ and is in contact with the first contact region 412′; and a portion of the second electrode 32′ is disposed on the surface of the second contact region 413′ and is in contact with the second contact region 413′. Herein, the first electrode 31′ and the second electrode 32′ may each adopt a stacked structure of molybdenum-niobium alloy (MoNb)/copper (Cu)/molybdenum-niobium alloy (MoNb), and the semiconductor layer 41′ may be made of indium gallium zinc oxide (IGZO).

According to the research of the inventors of the present application, it is found that when the metal film for forming the first electrode 31′ and the second electrode 32′ is deposited, the molybdenum element in the metal film (molybdenum-niobium alloy) in contact with the active layer will permeate the surface layer of the active layer to form an intrusion layer 42′, which is a part of the semiconductor layer 41′ where the molybdenum element intrudes. The channel region 411′, the first contact region 412′, and the second contact region 413′ are all overlapped with the orthographic projection of the intrusion layer 42′ on the base substrate 101′. In magnetron sputtering deposition of metal films, the molybdenum element has high kinetic energy, which will break the M-O bond in the indium gallium zinc oxide (M is In, Ga, and Zn). During the later heat treatment, the permeated molybdenum element will compete for the oxygen in the indium gallium zinc oxide, resulting in the increase of oxygen vacancies in the active layer. Upon the oxygen vacancies increase to a certain amount, the thin film transistor (TFT) will be made conductive (Vth negative shift).

FIG. 1b is a graph of an X-ray Photoelectron Spectrometer (XPS) of a transistor in a display substrate in the related art. Herein, the ordinate in FIG. 1b shows contents of elements in the stacked film layers of the intrusion layer and the active layer. The elements include oxygen (O), carbon (C), gallium (Ga), zinc (Zn), indium (In) and molybdenum (Mo). The abscissa in FIG. 1b shows depths of the stacked film layers of the intrusion layer and the active layer. As shown in FIG. 1b, the thickness of the intrusion layer in the display substrate in the related art is about 9 nm, that is, the active layer is permeated by molybdenum element (Mo) to a depth of about 9 nm. When etched to form the first electrode 31′ and the second electrode 32′, the intrusion layer on the channel region of the active layer is not completely etched (the etching depth of the active layer<2 nm), and therefore, the intrusion layer remains on the channel region of the active layer, and the intrusion layer will cause the thin film transistor (TFT) to be made conductive (Vth negative shift).

In the cell test of the display substrate in the related art, the incidence of driving bright spots is up to 80%, and a GOA abnormal display occurs frequently.

In the test of transistor characteristics of the display substrate in the related art, the Vth at the OK point of the transistor of the display substrate in the related art is about 2.0 V, the Vth at the driving bright spot is negatively shifted to about −9.0 V, and even some transistors are directly made conductive and lose the switching characteristic.

Although the probability that a single transistor is made conductive is low, some transistors in the display substrate will inevitably be made conductive since the display substrate includes millions of transistors, which will lead to poor performance of the display substrate. For example, the incidence of driving bright spots (pixel transistors are made conductive) is high and an abnormal display (a GOA transistor is made conductive) occurs frequently, a product yield decreases, and more seriously, transistors may be made conductive during the reliability process, reducing product quality.

An embodiment of the present disclosure provides a display substrate, which includes: a base substrate and a transistor disposed on the base substrate.

The transistor includes:
a semiconductor layer, including contact regions and a channel region located between the contact regions;
a contact electrode, at least a portion of which is disposed on a side of a contact region away from the base substrate and electrically connected to the contact region, and the material of which includes a first element; and
an auxiliary layer, disposed between the contact electrode and the semiconductor layer, a surface of a side of the auxiliary layer away from the base substrate being in contact with the contact electrode, a surface of a side of the auxiliary layer close to the base substrate being in contact with the contact regions, the auxiliary layer including a host material and a second element, the first element and the second element having a same atomic number, and the host material being the same as a material of the contact region.

In an exemplary implementation, the auxiliary layer is disposed between the contact electrode and the contact region of the semiconductor layer, at least a portion of the channel region is not overlapped with an orthographic projection of the auxiliary layer on the base substrate, and the auxiliary layer and the contact regions are of an integrated structure.

In an exemplary implementation, a vertical distance between the surface of a side of the auxiliary layer away from the base substrate and a surface of the base substrate is L3, and a vertical distance between the surface of a side of the channel region away from the base substrate and the surface of the base substrate is L2, and L3≥L2>2 nm.

In an exemplary implementation, 2 nm≤|L3−L2|≤20 nm.

In an exemplary implementation, the contact region includes a side surface close to a side of the channel region, and a slope angle of the side surface is 500 to 60°.

Solutions of the embodiments will be described below through some examples.

The transistor in the display substrate according to an embodiment of the present disclosure being used as the thin film transistor in the pixel circuit layer will be described as an example hereinafter, but the display substrate according to an embodiment of the present disclosure is not limited thereto. In another embodiment, the transistor in the display substrate according to an embodiment of the present disclosure may also be used as a thin film transistor in a gate drive circuit (GOA).

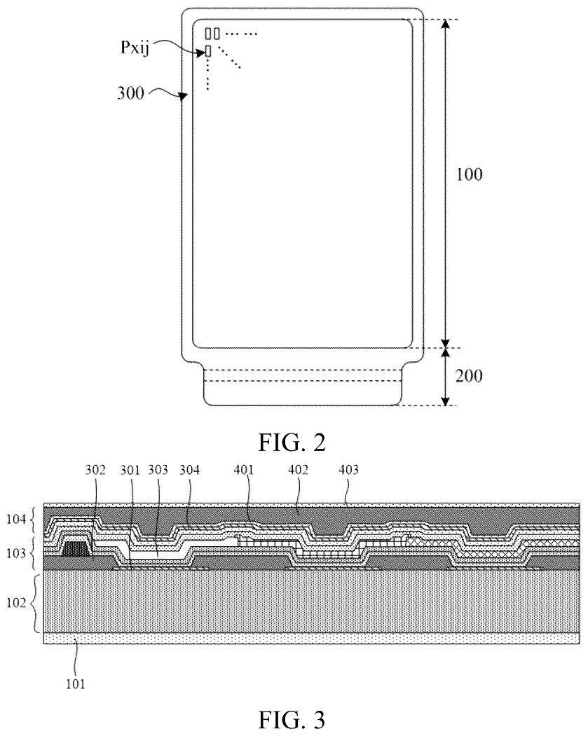

FIG. 2 is a schematic structural diagram of a display substrate panel according to an embodiment of the present application. In an exemplary implementation, as shown in FIG. 2, the display substrate may include a display area 100, a bonding area 200 located on a side of the display area 100, and a bezel area 300 located at other sides of the display area 100. In some examples, the display region 100 may be a planar region including a plurality of sub-pixels Pxij that form a pixel array, the plurality of sub-pixels Pxij may be configured to display a dynamic picture or a static image, and the display region 100 may be referred to as an Active region (AA).

In an exemplary implementation, the display substrate includes a display area 100 with a rectangular shape. In some embodiments, the display region 100 may also have a circular shape, an elliptical shape, or a polygonal shape such as a triangle and a pentagon.

In an exemplary implementation, the display substrate may be a pad display substrate. In some embodiments, the display substrate may be other types of display substrates as well, such as a flexible display substrate, a foldable display substrate, a rollable display substrate, and the like.

In some exemplary embodiments, the bonding region 200 may include a fan-out region, a bending region 202, a drive chip region, and a bonding pin region that are disposed sequentially along a direction away from the display region 100. The fan-out region is connected to the display region 100 and at least includes data fan-out lines. Multiple data fan-out lines are configured to be connected with the data signal lines of the display region 100 in a fan-out routing manner. The bending region is connected to the fan-out region and may include a composite insulating layer provided with a groove, and is configured to enable the drive chip region and the bonding pin region to be bent to a back of the display region 100. An integrated circuit (IC) may be disposed in the drive chip region, and the integrated circuit may be configured to be connected with the plurality of data fan-out lines. The bonding pin region may include a bonding pad, and the bonding pad may be configured to be bonded and connected with an external flexible printed circuit (FPC).

In an exemplary implementation, the display substrate may include a plurality of pixel units arranged in a matrix. For example, at least one pixel unit may include a first sub-pixel emitting first-color light, a second sub-pixel emitting second-color light, and a third sub-pixel and a fourth sub-pixel emitting third-color light.

In an exemplary implementation, the first sub-pixel may be a red sub-pixel (R) emitting red light, the second sub-pixel may be a blue sub-pixel (B) emitting blue light, and the third sub-pixel and the fourth sub-pixel may be green sub-pixels (G) emitting green light. In some examples, a shape of a light emitting structure layer of a sub-pixel may be a rectangle, a diamond, a pentagon, or a hexagon. Light emitting structure layers of four sub-pixels may be arranged in a diamond-shaped manner to form an RGBG pixel arrangement. In other exemplary embodiments, the light emitting structure layers of four sub-pixels may be arranged side by side horizontally, side by side vertically, or in a manner of a square, etc., which is not limited here in the present disclosure. In some other exemplary embodiments, the pixel unit may include three sub-pixels, the light emitting structure layers of the three sub-pixels may be arranged side by side horizontally, side by side vertically, or in a triangle-shaped manner, which is not limited in the present disclosure.

In an exemplary implementation, a sub-pixel Pxij may include a pixel circuit layer and a light emitting structure layer. The pixel circuit layer is connected to a scan signal line, a data signal line, and a light emitting control line respectively. The pixel circuit layer may be configured to receive a data voltage transmitted by the data signal line under control of the scan signal line and the light emitting control line, and output a corresponding current to the light emitting structure layer. The light emitting structure layer in each sub-pixel is respectively connected to a pixel circuit layer of the sub-pixel where the light emitting structure layer is located, and is configured to emit light with a corresponding brightness in response to a current output by the pixel circuit layer of the sub-pixel where the light emitting structure layer is located.

In an exemplary implementation, the light emitting structure layer may include one of a liquid crystal light emitting device (LCD), an organic light emitting diode (OLED), a light emitting diode (LED), and a quantum dot light emitting diode (QLED). The sub-pixel may emit light, such as red light, green light, blue light or white light, through the light emitting structure layer.

In an exemplary implementation, the display substrate is of a top-emitting type, a bottom-emitting type, a double-emitting type, or the like. In the top-emission type, the visible light emitted from the light emitting structure layer can irradiate an area in front of the display substrate to display an image; in the bottom-emission type, the visible light emitted from the light emitting structure layer can irradiate to an area behind the display substrate to display an image.

The light emitting structure layer in the display substrate according to an embodiment of the present disclosure including an organic light emitting diode (OLED) will be described as an example hereinafter, but the display substrate according to an embodiment of the present disclosure is not limited thereto. In another embodiment, the light emitting structure layer in the display substrate may include a light emitting diode (LED) or a quantum dot light emitting diode (QLED), etc. For example, a light emitting layer of the light emitting structure layer in the display substrate may include an organic material, an inorganic material, quantum dots, an organic material and quantum dots, an inorganic material and quantum dots, or an organic material, an inorganic material and quantum dots.

FIG. 3 is a cross-sectional view of a display substrate according to an embodiment of the present disclosure. FIG. 3 illustrates a cross-sectional view of three sub-pixels Pxij. In an exemplary implementation, the display substrate according to an embodiment of the present disclosure may include more sub-pixels Pxij (see FIG. 2). In addition, although the three sub-pixels Pxij are shown to be adjacent to each other in FIG. 3, the embodiments of the present disclosure are not limited thereto. That is, other assemblies, for example wirings, may be between the three sub-pixels Pxij. The three sub-pixels Pxij may not be pixels adjacent to each other. In FIG. 3, the sections of the three sub-pixels Pxij may not be sections in the same direction as the display substrate.

In an exemplary implementation, as shown in FIG. 3, the display substrate may include: a base substrate 101, and a pixel circuit layer 102, a light emitting structure layer 103, and an encapsulation structure layer 104 disposed sequentially on the base substrate 101, in a direction perpendicular to the display substrate. In some possible implementation modes, the display substrate may include another film layer, such as a touch structure layer, which is not limited here in the present disclosure.

In some exemplary embodiments, the base substrate 101 may be a flexible base substrate, or may be a rigid base substrate. When the base substrate 101 is a flexible base substrate, the base substrate 101 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The base substrate 101 may have a multi-layer structure, and the multi-layer structure includes two layers containing the above polymer resin and a barrier layer containing an inorganic material (e.g., silicon oxide, silicon nitride, or silicon oxynitride) between the two layers described above.

In some exemplary embodiments, the pixel circuit layer 102 of each sub-pixel may include a plurality of transistors and capacitors. The transistors may include an active layer, a source electrode, a drain stage, a gate, and the like.

In some exemplary embodiments, the light emitting structure layer 103 of each sub-pixel may at least include an anode 301, a pixel definition layer 302, an organic light emitting layer 303, and a cathode 304. The anode 301 is connected with a pixel circuit. The organic light emitting layer 303 is connected with the anode 301. The cathode 304 is connected with the organic light emitting layer 303. The organic light emitting layer 303 emits light of a corresponding color under driving of the anode 301 and the cathode 304.

In some exemplary embodiments, the encapsulation structure layer 104 may include a first encapsulation layer 401, a second encapsulation layer 402, and a third encapsulation layer 403 that are stacked. The first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 to form a stacked structure of inorganic material/organic material/inorganic material, which may ensure that external moisture cannot enter the light emitting structure layer 103.

In some exemplary embodiments, the organic light emitting layer 303 may include an emitting layer (EML), and any one or more of following layers: a hole injection layer (HIL), a hole transport layer (HTL), an electron block layer (EBL), a hole block layer (HBL), an electron transport layer (ETL), and an electron injection layer (EIL). In some examples, one or more layers of hole injection layers, hole transport layers, electron block layers, hole block layers, electron transport layers, and electron injection layers of all sub-pixels may be a common layer with various layer being connected together. Emitting layers of adjacent sub-pixels may be overlapped slightly, or may be mutually isolated.

FIG. 4 is a first cross-sectional view of a transistor in a display substrate according to an embodiment of the present disclosure. FIG. 4 illustrates a cross-sectional view of a transistor. In an exemplary implementation, the display substrate according to an embodiment of the present disclosure may include more transistors.

In an exemplary implementation, as shown in FIG. 4, the display substrate according to an embodiment of the present disclosure includes at least one transistor. The transistor includes a base substrate 101, and a gate 21, a gate insulating layer 51, a semiconductor layer 41, auxiliary layers 42, and contact electrodes 30 disposed sequentially in a direction away from the base substrate 101.

In an exemplary implementation, as shown in FIG. 4, the gate 21 is located on a side of the semiconductor layer 41 close to the base substrate 101, and an orthographic projection of the gate 21 is overlapped with an orthographic projection of the semiconductor layer 41 on the base substrate 101 and the gate 21 is insulated from the semiconductor layer 41. Exemplarily, the orthographic projection of the semiconductor layer 41 on the base substrate 101 is located within the orthographic projection of the gate 21 on the base substrate 101.

In an exemplary implementation, as shown in FIG. 4, the gate insulating layer 51 may be made of an inorganic material. Exemplarily, the gate insulating layer 51 may be made of any one or more of a silicon oxide (SiOx), a silicon nitride (SiNx), and a silicon oxynitride (SiON), and the gate insulating layer 51 may be a single layer, multiple layers, or a composite layer.

In some exemplary embodiments, the gate insulating layer 51 may be formed on the base substrate 101 using chemical vapor deposition (CVD) or atomic layer deposition.

In an exemplary implementation, as shown in FIG. 4, a semiconductor layer 41 is disposed on the gate insulating layer 51 and the semiconductor layer 41 is insulated from the gate 21 through the gate insulating layer 51. The semiconductor layer 41 may be used as an active layer of the transistor.

In an exemplary implementation, the material of the semiconductor layer 41 is one or more of metal oxide, amorphous silicon, and polysilicon. Exemplarily, the metal oxide may be at least one of Indium Gallium Zinc Oxide (IGZO), Indium Tin Zinc Oxide (ITZO), Indium Gallium Oxide (IGGO), Indium Gallium Zinc Tin Oxide (IGZTO), Indium Zinc Aluminum Oxide (IAZO), and Lanthanide Doped Metal Oxide (Ln-OS).

In an exemplary implementation, as shown in FIG. 4, the semiconductor layer 41 includes a first contact region 412 and a second contact region 413 and a channel region 411 located between the first contact region 412 and the second contact region 413. Both the first contact region 412 and the second contact region 413 are connected to the channel region 411.

In an exemplary implementation, as shown in FIG. 4, the auxiliary layers 42 are located on the first contact region 412 and the second contact region 413 respectively, and orthographic projections of the auxiliary layers 42 are all overlapped with the orthographic projections of the first contact region 412 and the second contact region 413 on the base substrate 101. Exemplarily, the orthographic projections of the auxiliary layers 42 are all completely overlapped with the orthographic projections of the first contact region 412 and the second contact region 413 on the base substrate 101. During the process of forming the contact electrodes 30, the first element of the contact electrodes 30 intrudes into the surface layer of the semiconductor layer 41 to form the auxiliary layers 42. The auxiliary layers 42 can cause a transistor to be conductive (Vth negative shift). Therefore, in the display substrate according to an embodiment of the present disclosure, the orthographic projection of at least a portion of the channel region 411 is not overlapped with the orthographic projections of the auxiliary layers 42 on the base substrate 101, and exemplarily, the orthographic projection of the channel region 411 is not overlapped with the orthographic projections of the auxiliary layers 42 on the base substrate 101.

In the display substrate according to an embodiment of the present disclosure, by etching and removing the auxiliary layers 42 on at least a portion of the channel region 411, no auxiliary layer 42 is provided on at least a portion of the channel region 411, thus avoiding the problem that the first element of the contact electrodes 30 intrudes into the channel region 411 to result in conducting during the process of forming the contact electrodes 30.

In the display substrate according to an embodiment of the present disclosure, taking advantage of the diffusion of the first element of the contact electrodes 30, under the same mask condition and by controlling the etching conditions and the thickness ranges of the semiconductor layer and the auxiliary layer, the auxiliary layers 42 are added to improve the conductivity of the contact region while ensuring the TFT characteristics.

In an exemplary implementation, as shown in FIG. 4, a portion of the contact electrode 30 is disposed on the gate insulating layer 51, and a portion of the contact electrode 30 is disposed on the first contact region 412/the second contact region 413, and is connected to the first contact region 412/the second contact regions 413. The contact electrode 30 covers the side and a portion of the surface of the first contact region 412/the second contact regions 413, and orthographic projections of the contact electrodes 30 are not overlapped with the orthographic projection of the channel region 411 on the base substrate 101. The contact electrode 30 may be used as a source-drain electrode of the transistor.

In an exemplary implementation, the contact electrodes 30 may adopt a single-layer metal structure. For example, the contact electrode 30 may be of a single metal layer such as aluminum (Al), copper (Cu) or the like. Or, the contact electrode 30 may be of a multi-layer metal structure, including a first material layer, a second material layer, and a third material layer disposed between the first material layer and the second material layer. The first material layer and the second material layer may each adopt molybdenum (Mo) or molybdenum-niobium alloy (MoNb), and the third material layer may adopt aluminum (Al) or copper (Cu).

In an exemplary implementation, the material of the contact electrodes 30 includes a first element. When the contact electrodes 30 are of aluminum (Al) metal layers, the first element is an aluminum element. When the contact electrodes 30 are of copper (Cu) metal layers, the first element is a copper element. When the contact electrodes 30 adopt a multi-layer metal structure and the first material layer and the second material layer each adopt molybdenum (Mo), the first element is molybdenum element. When the contact electrodes 30 adopt a multi-layer metal structure and the first material layer and the second material layer adopt molybdenum-niobium alloy (MoNb), the first element is a molybdenum element and/or niobium element.

In an exemplary implementation, as shown in FIG. 4, the auxiliary layers 42 are located between the contact electrode 30 and the first contact region 412 and between the contact electrode 30 and the second contact region 413. Orthographic projections of the auxiliary layers 42 are all overlapped with the orthographic projections of the first contact region 412 and the second contact region 413 on the base substrate 101, and, exemplarily, orthographic projections of the auxiliary layers 42 are all completely overlapped with the orthographic projections of the first contact region 412 and the second contact region 413 on the base substrate 101. The orthographic projections of the auxiliary layers 42 are not overlapped with the orthographic projection of at least a portion of the channel region 411 on the base substrate 101, so that no auxiliary layer 42 is provided on at least a portion of the channel region 411.

In an exemplary implementation, the auxiliary layers 42 are part of the first contact region 412 and the second contact region 413 that is intruded by the first element of the contact electrodes 30. The surfaces of a side of the auxiliary layers 42 away from the base substrate 101 are in contact with the contact electrodes 30, and the surfaces of a side of the auxiliary layers 42 close to the base substrate 101 and the first contact region 412 and the second contact region 413 are of an integral structure.

In an exemplary implementation, the auxiliary layer 42 includes: a second element having the same atomic number with the first element of the contact electrode 30, and a host material which is the same material as the first contact region 412 or the second contact region 413. Exemplarily, the semiconductor layer 41 adopts indium gallium zinc oxide (IGZO), the contact electrode 30 adopts a stacked structure of molybdenum-niobium alloy (MoNb)/copper (Cu)/molybdenum-niobium alloy (MoNb), the second element of the auxiliary layer 42 is molybdenum, and the host material of the auxiliary layer 42 is the indium gallium zinc oxide.

In an exemplary implementation, the second element of the auxiliary layers 42 and the first element of the contact electrodes 30 may be the same element. For example, both of the second element of the auxiliary layers 42 and the first element of the contact electrodes 30 may be the molybdenum element.

In an exemplary implementation, the first element and the second element include at least one of aluminum, copper, molybdenum, nickel, titanium, and niobium.

In an exemplary implementation, the second element of the auxiliary layers 42 and the first element of the contact electrodes 30 may be metal ions of different valence states. For example, the second element of the auxiliary layers 42 may be Fe²⁺ ions, and the first element of the contact electrodes 30 may be Fe³⁺ ions.

In an exemplary implementation, the second element of the auxiliary layers 42 and the first element of the contact electrodes 30 may be isotopes. For example, both of the second element of the auxiliary layers 42 and the first element of the contact electrodes 30 may be an isotope of molybdenum.

In an exemplary implementation, the second element of the auxiliary layers 42 includes at least one of aluminum, copper, molybdenum, nickel, titanium, and niobium. The second element of the auxiliary layers 42 is the first element of the contact electrodes 30 intruding into the semiconductor layer 41.

In an exemplary implementation, when the contact electrode 30 is of an aluminum (Al) metal layer, the second element is the aluminum element; when the contact electrode 30 is of a copper (Cu) metal layer, the second element is a copper element; when the contact electrode 30 adopts a multi-layer metal structure and the first material layer and the second material layer each adopts molybdenum (Mo), the second element is the molybdenum element; when the contact electrode 30 adopts a multi-layer metal structure and the first material layer and the second material layer adopt a molybdenum-niobium alloy (MoNb), the second element is the molybdenum element and/or niobium element.

In an exemplary implementation, the thickness of the auxiliary layers 42 is 2 nm to 20 nm. The etching depth of the channel region 411 is 2 nm to 20 nm during the formation of the contact electrodes 30, so as to completely etch off the auxiliary layers 42 on the channel region 411. When the etching depth of the channel region 411 is less than 2 nm, the auxiliary layers 42 on the channel region 411 cannot be completely removed. When the etching depth of the channel region 411 is greater than 20 nm, on the one hand, the thickness of the channel region 411 is too small, which leads to a decrease in the Ion of the transistor. When the etching depth of the channel region 411 is 21.1 nm, the Ion of the transistor decreases by about 20%, accompanied by a deterioration of ss, as shown in Table 1. On the other hand, since the channel region 411 and the contact electrodes 30 are etched at the same time, when the etching depth of the channel region 411 is greater than 20 nm, the contact electrode 30 may be etched excessively, and the line width of the contact electrode 30 cannot be guaranteed.

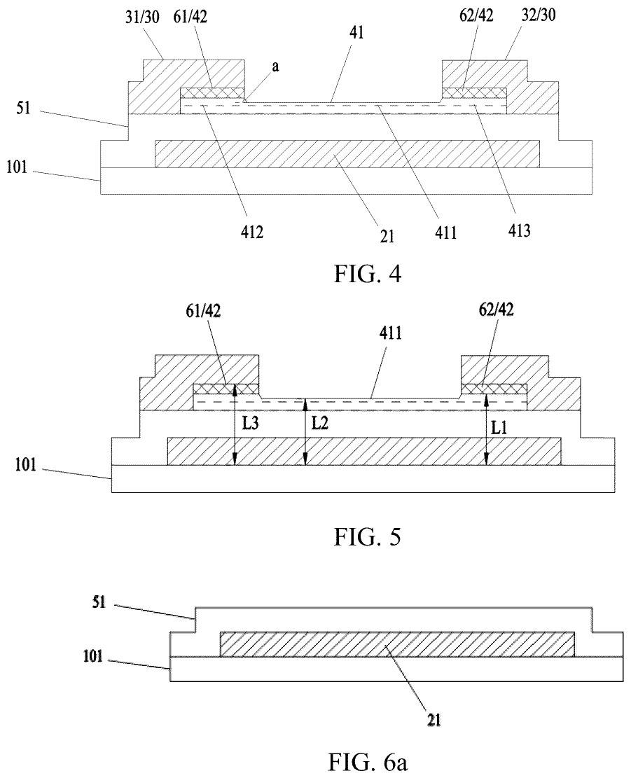

FIG. 5 is a second cross-sectional view of a transistor in a display substrate according to an embodiment of the present disclosure. In an exemplary implementation, as shown in FIG. 5, a vertical distance between the surface of a side of the auxiliary layers 42 away from the base substrate 101 and a surface of the base substrate 101 is L3, and a vertical distance between the surface of a side of the channel region 411 away from the base substrate 101 and the surface of the base substrate 101 is L2, and L3≥L2>2 nm. Therefore, the etching depth of the channel region 411 is greater than 2 nm, ensuring that the auxiliary layer 42 on the channel region 411 is completely etched off.

In an exemplary implementation, 2 nm≤|L3−L2|≤20 nm, ensuring that the etching depth of the channel region 411 is greater than or equal to 2 nm and less than or equal to 20 nm. Therefore, it is ensued that the channel region 411 has a certain thickness while the auxiliary layer 42 on the channel region 411 is completely etched off.

In an exemplary implementation, the ratio of the thickness of the auxiliary layers 42 to the thickness of the contact regions is 1:10 to 1:3. The ratio of the thickness of the contact regions to the thickness of the channel region is 1:1 to 5:1. Exemplarily, the thickness of the auxiliary layers 42 is 2 nm to 20 nm, the thickness of the contact regions is 6 nm to 200 nm, and the thickness of the channel region is 6 nm to 180 nm.

In an exemplary implementation, the content of the second element in the auxiliary layers 42 is 0.1% to 10%. Exemplarily, when the second element of the auxiliary layers 42 is molybdenum and the host material of the auxiliary layers 42 is indium gallium zinc oxide, the content of molybdenum in the auxiliary layers 42 is 0.1% to 10%. The semiconductor layer 41 (e.g. indium gallium zinc oxide) in which the content of the second element (e.g. molybdenum) is 0.1% to 10% has the problem of being made conductive, and therefore the auxiliary layer 42 on the channel region 411 needs to be etched off.

In an exemplary implementation, the content of the first element in the first contact region 412 or the second contact region 413 is less than 0.1%. The semiconductor layer 41 (e.g. indium gallium zinc oxide) in which the content of a metal element (e.g. molybdenum) is less than 0.1% will not be made conductive.

In an exemplary implementation, as shown in FIG. 5, the distance L1 between the surface of a side of the auxiliary layers 42 close to the base substrate 101 and the surface of the base substrate 101, is greater than or equal to the distance L2 between the surface of a side of the channel region 411 away from the base substrate 101 and the surface of the base substrate 101. That is, the height of the surface of a side of the auxiliary layers 42 close to the base substrate 101 is not less than the height of the surface of a side of the channel region 411 away from the base substrate 101, thereby ensuring that the etching depth of the channel region 411 is greater than the thickness of the auxiliary layers 42, so that the auxiliary layers 42 on the channel region 411 can be completely etched off without residue. The surface of the base substrate 101 is a surface of a side of the base substrate 101 close to the semiconductor layer 41.

In the exemplary embodiment, as shown in FIG. 5, the difference between the distance L3 between the surface of a side of the auxiliary layers 42 away from the base substrate 101 and the surface of the base substrate 101, and the distance L2 between the surface of a side of the channel region 411 away from the base substrate 101 and the surface of the base substrate 101, is 2 nm to 20 nm, so that the etching depth of the channel region 411 is 2 nm to 20 nm. Since the intruded depth of the channel region 411 by the first element is generally 2 nm to 20 nm, by etching the channel region 411 by 2 nm to 20 nm, the auxiliary layers 42 on the channel region 411 can be completely etched off without residue.

TABLE 1
Characteristics of channel region of transistor after being etched

| ITEM | | Ion(uA) | Ioff(pA) | Vth | Mob | sst |
|---|---|---|---|---|---|---|
| Etching | 1# | 10.14 | 3.03 | 2.84 | 11.90 | 0.53 |
| depth of | 2# | 10.36 | 4.91 | 2.43 | 11.63 | 0.60 |
| channel region | 3# | 10.12 | 2.38 | 2.41 | 11.57 | 0.68 |
| IGZO, 8.7 nm | Avg | 10.21 | 3.44 | 2.56 | 11.70 | 0.60 |
| Etching | 1# | 7.96 | 7.53 | 3.30 | 9.99 | 0.62 |
| depth of | 2# | 8.29 | 3.82 | 2.80 | 9.83 | 0.70 |
| channel region | 3# | 8.34 | 2.27 | 2.68 | 9.83 | 0.78 |
| IGZO, 21.1 nm | Avg | 8.19 | 4.54 | 2.93 | 9.88 | 0.70 |

In an exemplary embodiment, for example, the contact electrode 30 adopts a stacked structure of molybdenum-niobium alloy (MoNb)/copper (Cu)/molybdenum-niobium alloy (MoNb), and the semiconductor layer 41 adopts indium gallium zinc oxide (IGZO). The second element of the auxiliary layers 42 is molybdenum. A difference between a distance L3 of the surface of a side of the auxiliary layers 42 away from the base substrate 101 to the surface of the base substrate 101, and a distance L2 of a surface of a side of the channel region 411 away from the base substrate 101 to the surface of the base substrate 101, is greater than or equal to 9 nm and less than or equal to 20 nm, so that the etching depth of the channel region 411 is 9 nm to 20 nm, and the auxiliary layers 42 on the channel region 411 can be completely etched off without residue.

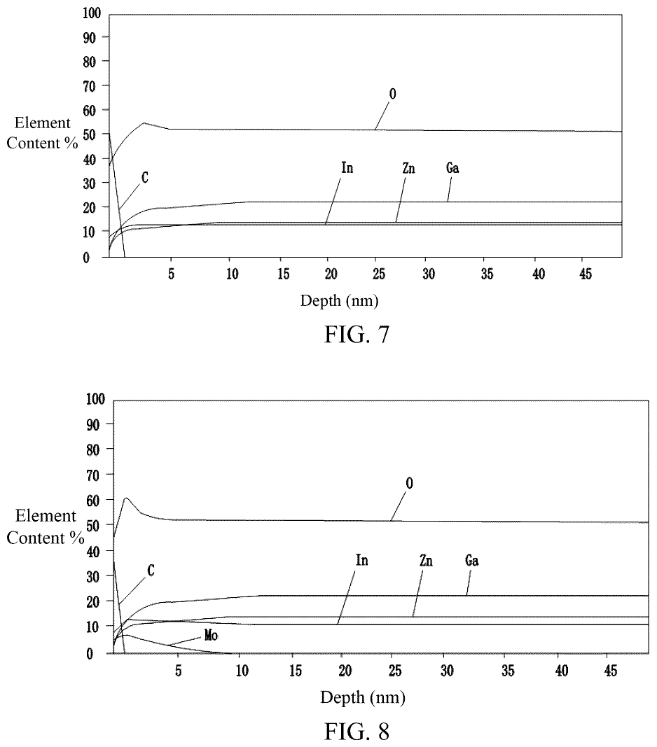

FIG. 7 is a graph of an X-ray Photoelectron Spectrometer (XPS) of a channel region of a semiconductor layer in a base substrate according to an embodiment of the present disclosure. FIG. 8 is a graph of an X-ray Photoelectron Spectrometer (XPS) of a contact region of a semiconductor layer in a base substrate according to an embodiment of the present disclosure. For example, the contact electrode 30 adopts a stacked structure of molybdenum-niobium alloy (MoNb)/copper (Cu)/molybdenum-niobium alloy (MoNb), the semiconductor layer 41 is made of indium gallium zinc oxide (IGZO), and the etching depth of the semiconductor layer 41 is 9 nm. As shown in FIG. 7, XPS analysis is performed on the channel region of the semiconductor layer in the display substrate according to an embodiment of the present disclosure, the channel region of the semiconductor layer is free of molybdenum element, and the intruded portion of the channel region in the semiconductor layer is completely removed. As shown in FIG. 8, XPS analysis is performed on the contact region of the semiconductor layer in the display substrate according to an embodiment of the present disclosure, and the thickness of the auxiliary layer on the contact region is about 9 nm.

In an exemplary implementation, as shown in FIG. 4, the first contact region 412 and the second contact region 413 each includes a side surface close to a side of the channel region 411. The slope angle “a” of the side surface of the first contact region 412 and the side surface of the second contact region 413 is 50° to 60°, so that the side surfaces are gentle and a large segment difference is avoided. The side surface of the first contact region 412, the side surface of the second contact region 413, and the surface of a side of the channel region 411 away from the base substrate 101 form a groove, which is a U-shaped groove in a cross section perpendicular to the base substrate 101. In some other embodiments, the groove may also be of other shapes and embodiments of the present disclosure will not be repeated herein.

In an exemplary implementation, as shown in FIG. 4, a transistor of a display substrate according to an embodiment of the present disclosure includes a first contact electrode 31 and a second contact electrode 32. At least a portion of the first contact electrode 31 is disposed on a side of the first contact region 412 away from the base substrate 101 and connected to the first contact region 412. At least a portion of the second contact electrode 32 is disposed on a side of the second contact region 413 away from the base substrate 101 and connected to the second contact region 413. The first contact electrode 31 may be used as a source electrode of the transistor and the second contact electrode 32 may be used as a drain electrode of the transistor. Or, the first contact electrode 31 may be used as a drain electrode of the transistor and the second contact electrode 32 may be used as a source electrode of the transistor.

In an exemplary implementation, as shown in FIG. 4, a transistor of a display substrate according to an embodiment of the present disclosure includes a first auxiliary layer 61 and a second auxiliary layer 62. The first auxiliary layer 61 is disposed between the first contact electrode 31 and the first contact region 412, the surface of a side of the first auxiliary layer 61 away from the base substrate 101 is in contact with the first contact electrode 31, and the surface of a side of the first auxiliary layer 61 close to the base substrate 101 and the first contact region 412 are in an integral structure. The first contact electrode 31 includes a first element, the first auxiliary layer 61 includes a second element and a first host material, the second element has the same atomic number as the first element, and the first host material is the same as the material of the first contact region 412. The second auxiliary layer 62 is disposed between the second contact electrode 32 and the second contact region 413, the surface of a side of the second auxiliary layer 62 away from the base substrate 101 is in contact with the second contact electrode 32, and the surface of a side of the second auxiliary layer 62 close to the base substrate 101 and the second contact region 413 are in an integral structure. The second contact electrode 32 includes a first element, the second auxiliary layer 62 includes a second element and a second host material, the second element has the same atomic number as the first element, and the second host material is the same as the material of the second contact region. The orthographic projection of the channel region 411 is not overlapped with the orthographic projections of the first auxiliary layer 61 and the second auxiliary layer 62 on the base substrate 101.

An embodiment of the present disclosure further provides a method for preparing a display substrate, including:
forming a semiconductor layer on a base substrate, the semiconductor layer including a channel region and a contact region located on at least one side of the channel region;
forming a metal film covering the semiconductor layer on the base substrate, the metal film including a first element, the first element of at least a portion of the metal film intruding into the semiconductor layer to form an auxiliary film;
forming a contact electrode with the metal film through a patterning process, and exposing the auxiliary film on the channel region;
removing the exposed auxiliary film on at least a portion of the channel region, exposing a surface of at least the portion of the channel region, retaining the auxiliary film on the contact region to form an auxiliary layer with the auxiliary film, the auxiliary layer including a second element and a host material, the second element being the same as the first element, and the host material being the same as the material of the contact region.

In an exemplary implementation, the same patterning process is used to form the contact electrode with the metal film and to remove the exposed auxiliary film on at least the portion of the channel region.

In an exemplary implementation, removing the exposed auxiliary film on at least the portion of the channel region includes:
etching the metal film with an etching liquid to form the contact electrode with the metal film and to expose the auxiliary film on the channel region;
etching the exposed auxiliary film on at least the portion of the channel region with the etching liquid to remove the exposed auxiliary film on the channel region.

In an exemplary implementation, a ratio of an etching rate of the metal film in the etching liquid to an etching rate of the auxiliary film in the etching liquid is 50:1 to 5:1.

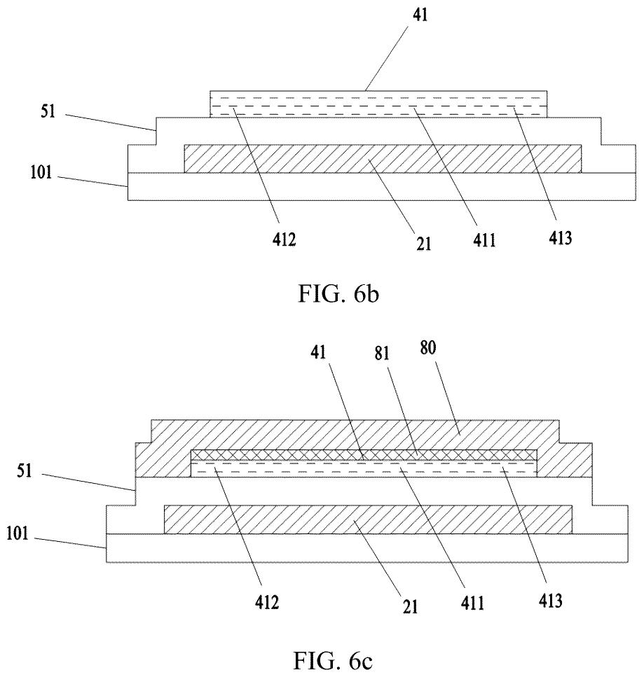

An exemplary description of a method for preparing a display substrate will be given below with reference to FIGS. 6a to 6c.

A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, and the present disclosure is not limited thereto. A “thin film” refers to a layer of thin film made of a material on a base substrate by using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.
Act S1, forming a gate. Forming the gate includes: depositing a first conductive film on a base substrate 101, and forming a gate 21 with the first conductive film by a patterning process; and then depositing an insulating film covering the gate 21 on the base substrate 101, and forming a gate insulating layer 51 with the insulating film by a patterning process, as shown in FIG. 6a.
Act S2, forming a semiconductor layer. Forming the semiconductor layer includes: based on the base substrate 101 on which the aforementioned pattern is formed, depositing an oxide semiconductor film on the gate insulating layer 51, and forming a semiconductor layer 41 with the oxide semiconductor film by a patterning process, as shown in FIG. 6b. The semiconductor layer 41 includes a channel region 411 and a first contact region 412 and a second contact region 413 located on the opposite two sides of the channel region 411; both of the first contact region 412 and the second contact region 413 are connected to the channel region 411.
Act S3, forming a metal film. Forming the metal film includes: based on the base substrate 101 on which the aforementioned patterns are formed, depositing, on the gate insulating layer 51, a metal film 80 covering the semiconductor layer 41. The metal film 80 includes a first element, the first element in the metal film 80 intrudes into the semiconductor layer 41, and an auxiliary film 81 is formed on the surface layer of the semiconductor layer 41. Exemplarily, the first element may be molybdenum element, and the molybdenum element intrudes into the surface layer of the semiconductor layer 41 to form the auxiliary film 81, as shown in FIG. 6c.
Act S4, forming a contact electrode. Forming the contact electrode includes: based on the base substrate 101 on which the aforementioned patterns are formed, etching the metal film 80 with an etching liquid, forming a first contact electrode 31 and a second contact electrode 32 with the metal film 80, and exposing the auxiliary film 81 on the channel region 411 of the semiconductor layer 41; after the etching time of the metal film 80 with etching liquid is increased to form the first contact electrode 31 and the second contact electrode 32 with the metal film 80, etching the auxiliary film 81 exposed on the channel region 411 with the etching liquid, removing the auxiliary film 81 exposed on the channel region 411 to expose the surface of the channel region 411, and retaining the auxiliary film 81 on the first contact region 412 and the second contact region 413 to form the auxiliary layers 42 (e.g., the first auxiliary layer 61 and the second auxiliary layer 62) with the auxiliary film 81 on the first contact region 412 and the second contact region 413, as shown in FIG. 4. The auxiliary layers 42 include a second element and a host material, the second element has the same atomic number with the first element of the metal film 80, and the host material is the same material as the first contact region 412 and the second contact region 413.

In an exemplary implementation, the ratio of an etching rate of the metal film in the above etching liquid to an etching rate of the auxiliary film in the above etching liquid is 50:1 to 5:1. Exemplarily, when the first contact electrode 31 and the second contact electrode 32 are both made of the copper metal layer and the semiconductor layer 41 is made of indium gallium zinc oxide (IGZO), the etching liquid may adopt an H₂O₂-based Cu etching liquid, and the ratio of the etching rate of the metal film in the etching liquid to the etching rate of the auxiliary film in the etching liquid is 19:1.

When the ratio of the etching rate of the metal film in the etching liquid to the etching rate of the auxiliary film in the etching liquid is too large, the etching rate of the auxiliary film in the etching liquid will be too slow, and the time needed for etching the auxiliary film on the channel region 411 will be long, which will cause the etching amount of the metal film too large and will not guarantee the line width of the first contact electrode 31 and the second contact electrode 32. When the ratio of the etching rate of the metal film in the etching liquid to the etching rate of the auxiliary film in the etching liquid is too small, the etching rate of the auxiliary film in the etching liquid will be too fast, and the film uniformity of the first contact electrode 31 and the second contact electrode 32 will be about 10%, so that within a short etching time, at a position where the film thickness of the first contact electrode 31 and the second contact electrode 32 is too thick, the etching depth of the auxiliary film on the channel region 411 will be lower than the set value, and the auxiliary film on the channel region 411 will not be completely etched off.

The present disclosure further provides a display apparatus, including a display substrate according to the aforementioned embodiments. The display apparatus may be any product or component with a display function, such as a mobile phone, a tablet computer, a television, a display, a laptop computer, a digital photo frame, or a navigator.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict.

Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising: a base substrate and a transistor disposed on the base substrate; wherein
the transistor comprises:
a semiconductor layer, comprising contact regions and a channel region located between the contact regions;
a contact electrode, at least a portion of which is disposed on a side of a contact region away from the base substrate and electrically connected to the contact region, and the material of which comprises a first element; and
an auxiliary layer, disposed between the contact electrode and the semiconductor layer, a surface of a side of the auxiliary layer away from the base substrate being in contact with the contact electrode, a surface of a side of the auxiliary layer close to the base substrate being in contact with the contact regions, the auxiliary layer comprising a host material and a second element, the first element and the second element having a same atomic number, and the host material being the same as a material of the contact region.

2. The display substrate according to claim 1, wherein the auxiliary layer is disposed between the contact electrode and the contact region of the semiconductor layer, at least a portion of the channel region is not overlapped with an orthographic projection of the auxiliary layer on the base substrate, and the auxiliary layer and the contact region are of an integrated structure.

3. The display substrate according to claim 2, wherein a vertical distance between the surface of the side of the auxiliary layer away from the base substrate and a surface of the base substrate is L3, and a vertical distance between a surface of a side of the channel region away from the base substrate and the surface of the base substrate is L2, and L3≥L2>2 nm.

4. The display substrate according to claim 3, wherein 2 nm≤|L3-L2|≤20 nm.

5. The display substrate according to claim 3, wherein the contact region comprises a side surface close to a side of the channel region, and a slope angle of the side surface is 50° to 60°.

6. The display substrate according to claim 1, wherein a content of the second element in the auxiliary layer is 0.1% to 10%.

7. The display substrate according to claim 1, wherein the contact regions comprise the first element and a material of the semiconductor, and a content of the first element in the contact regions is not more than 0.1%.

8. The display substrate according to claim 1, wherein a ratio of a thickness of the auxiliary layer to a thickness of the contact region is 1:10 to 1:3.

9. The display substrate according to claim 1, wherein a ratio of a thickness of the contact region to a thickness of the channel region is 1:1 to 5:1.

10. The display substrate according to claim 1, wherein the first element and the second element comprise at least one of aluminum, copper, molybdenum, nickel, titanium and niobium.

11. The display substrate according to claim 1, wherein a material of the semiconductor layer is one or more of a metal oxide, an amorphous silicon, and a polysilicon.

12. The display substrate according to claim 1, wherein the second element is molybdenum, and a difference between a distance of the surface of the side of the auxiliary layer away from the base substrate to a surface of the base substrate, and a distance of a surface of a side of the channel region away from the base substrate to a surface of the base substrate, is greater than or equal to 9 nm and less than or equal to 20 nm.

13. The display substrate according to claim 1, further comprising a gate located on a side of the semiconductor layer close to the base substrate and insulated from the semiconductor layer, the gate being overlapped with an orthographic projection of the channel region of the semiconductor layer on the base substrate.

14. The display substrate according to claim 1, wherein the contact electrode comprises a first material layer, a second material layer, and a third material layer disposed between the first material layer and the second material layer.

15. The display substrate according to claim 1, wherein the transistor comprises:
the semiconductor layer, comprising a first contact region, a second contact region and a channel region between the first contact region and the second contact region;
a first contact electrode and a second contact electrode, at least a portion of the first contact electrode being disposed on a side of the first contact region away from the base substrate and electrically connected to the first contact region, and at least a portion of the second contact electrode being disposed on a side of the second contact region away from the base substrate and electrically connected to the second contact region;
a first auxiliary layer, disposed between the first contact electrode and the first contact region, a surface of a side of the first auxiliary layer away from the base substrate being in contact with the first contact electrode, a material of the first contact electrode comprising a first element, the first auxiliary layer comprising a first host material and a second element, the first element and the second element having a same atomic number, and the first host material being the same as a material of the first contact region; and
a second auxiliary layer, disposed between the second contact electrode and the second contact region, a surface of a side of the second auxiliary layer away from the base substrate being in contact with the second contact electrode, a material of the second contact electrode comprising a first element, the second auxiliary layer comprising a second host material and a second element, the first element and the second element having the same atomic number, and the second host material being the same as the material of the second contact region.

16. A method for preparing a display substrate, comprising:
forming a semiconductor layer on a base substrate, wherein the semiconductor layer comprises contact regions and a channel region located between the contact regions;
forming a metal film covering the semiconductor layer on the base substrate, wherein a material of the metal film comprises a first element, the first element of at least a portion of the metal film intrudes into the semiconductor layer to form an auxiliary film;
forming a contact electrode with the metal film through a patterning process, and exposing the auxiliary film on the channel region; and
removing the exposed auxiliary film on at least a portion of the channel region, exposing a surface of at least the portion of the channel region, retaining the auxiliary film on the contact region to form an auxiliary layer with the auxiliary film, wherein the auxiliary layer comprises a host material and a second element, the first element and the second element have a same atomic number, and the host material is the same as a material of the contact region.

17. The method for preparing a display substrate according to claim 16, wherein the same patterning process is used to form the contact electrode with the metal film and to remove the exposed auxiliary film on at least the portion of the channel region.

18. The method for preparing a display substrate according to claim 17, wherein removing the exposed auxiliary film on at least the portion of the channel region comprises:
etching the metal film with an etching liquid to form the contact electrode with the metal film and to expose the auxiliary film on the channel region;
etching the exposed auxiliary film on at least the portion of the channel region with the etching liquid to remove the exposed auxiliary film on the channel region.

19. The method for preparing a display substrate according to claim 18, wherein a ratio of an etching rate of the metal film in the etching liquid to an etching rate of the auxiliary film in the etching liquid is 50:1 to 5:1.
